(19) United States
(12) Patent Application Publication
(10) Pub. No.: US 2004/0178470 A1
(43) Pub. Date: Sep. 16, 2004

(54) Semiconductor memory device and method of manufacturing the same

(76) Inventor: Katsuhiko Hieda, Yokohama-shi (JP)

Correspondence Address: Finnegan, Henderson, Farabow,, Garrett & Dunner, L.L.P., 1300 I Street, N.W., Washington, DC, 20005-3315, US

(21) Appl. No.: 10/611,229

(22) Filed: Jul. 2, 2003

(30) Foreign Application Priority Data
Mar. 14, 2003 (JP) 2003-070136

(51) Int. Cl. H01L 29/00

(52) U.S. Cl. 257/510

(57) ABSTRACT

An electrically erasable nonvolatile semiconductor memory device comprises a semiconductor substrate having a trench and a projecting portion which has a side surface defined by the trench, a gate structure comprising a first insulating-film formed on the projecting portion and having a side surface aligned with the side surface of the projecting portion, a first conductive-film formed on the first insulating-film and having a side surface aligned with the side surface of the first insulating-film, a second insulating-film formed on the first conductive-film and having a side surface aligned with the side surface of the first conductive-film, and a second conductive-film formed on the second insulating-film and having a side surface aligned with the side surface of the second insulating-film, the second insulating-film including a dielectric film having a dielectric constant higher than that of the first insulating-film, and a third insulating-film formed at least within the trench.

### CROSS-REFERENCE TO RELATED APPLICATIONS

This application is based upon and claims the benefit of priority from the prior Japanese Patent Application No. 2003-070136, filed Mar. 14, 2003, the entire contents of which are incorporated herein by reference.

### BACKGROUND OF THE INVENTION

1. Field of the Invention The present invention relates to an electrically erasable nonvolatile semiconductor memory device and a method of manufacturing the same.

2. Description of the Related Art

In recent years, demands for an electrically erasable nonvolatile semiconductor memory device such as an EEPROM (Electrically Erasable and Programmable ROM) have been increasing. Typical nonvolatile semiconductor memory devices include a NOR type flash memory and a NAND type flash memory in which a first insulating film (a tunnel insulating film), a first conductive film (a control gate), a second insulating film (an inter-polysilicon dielectrics) and a second conductive film (a control gate) are stacked one upon the other on a semiconductor substrate.

In a nonvolatile semiconductor memory device of this type, important is a capacitance ratio C2/C1 of a capacitance C2 between the floating gate and the control gate to a capacitance C1 between the semiconductor substrate and the floating gate. It is necessary for the capacitance ratio C2/C1 to be at least 2, in general, to be 3 or more. However, since an insulating film whose dielectric constant is not sufficiently high such as an ONO film is used as the second insulating film, it is rendered difficult to ensure a sufficiently high capacitance ratio C2/C1 in accordance with progress in the miniaturization of the device.

To overcome the difficulty noted above, it is proposed to form a capacitor by using the side surface of the floating gate so as to increase the capacitance C2. The particular technical idea is proposed in, for example, Japanese Patent Disclosure (Kokai) No. 8-17948. Specifically, it is proposed that a first insulating film is formed first on a semiconductor substrate, followed by forming a first conductive film on the first insulating film. Then, the first conductive film, the first insulating film and the semiconductor substrate were etched so as to form a trench for an isolation, followed by forming an insulating film for an isolation within the trench. In this case, the insulating film for the isolation is formed in a manner to permit a part of the side surface of the first conductive film to be exposed to the outside. Then, a second insulating film is formed on the upper surface and the side surface of the first conductive film, followed by forming a second conductive film. According to this proposal, the second insulating film and the second conductive film (a control gate) are formed on the side surface of the first conductive film (a floating gate), which makes it possible to increase the capacitance C2.

However, in the proposal described above, it is difficult to control accurately the exposed area of the side surface of the floating gate in forming the insulating film for the isolation. As a result, the value of the capacitance C2 is rendered nonuniform, leading to a nonuniform capacitance ratio C2/C1. It follows that the amount of electrons injected into the floating gate is rendered nonuniform, which lowers the reliability and the yield. Also, in the proposal described above, the control gate is positioned to face an upper corner of the floating gate so as, which increases the leakage current in the facing region, with the result that the reliability and the yield are caused to be lowered.

Another idea is proposed in, for example, Japanese Patent Disclosure (Kokai) No. 2-239671. Specifically, it is proposed that a first insulating film, a first conductive film, a second insulating film and a second conductive film are formed successively on a semiconductor substrate. Then, the first insulating film, the first conductive film, the second insulating film, the second conductive film and the semiconductor substrate are etched so as to form a trench for an isolation, followed by forming an insulating film for an isolation within the trench.

However, the proposal described above is directed to an EPROM (Erasable and Programmable ROM), which basically differs from the electrically erasable semiconductor memory device. Naturally, the capacitance ratio C2/C1 is not taken into account at all and, thus, each of the first insulating film and the second insulating film is formed of a silicon oxide film.

As described above, the problems that the capacitance ratio C2/C1 is changed and that the leakage current is increased remain unsolved in the prior art, which makes it difficult to obtain an electrically erasable nonvolatile semiconductor memory device excellent in the characteristics and the reliability.

### BRIEF SUMMARY OF THE INVENTION

According to a first aspect of the present invention, there is provided an electrically erasable nonvolatile semiconductor memory device, comprising:

a semiconductor substrate having a trench and a projecting portion which has a first side surface defined by the trench;

a first gate structure comprising a first insulating film formed on the projecting portion and having a first side surface aligned with the first side surface of the projecting portion, a first conductive film formed on the first insulating film and having a first side surface aligned with the first side surface of the first insulating film, a second insulating film formed on the first conductive film and having a first side surface aligned with the first side surface of the first conductive film, and a second conductive film formed on the second insulating film and having a first side surface aligned with the first side surface of the second insulating film, the second insulating film including a dielectric film having a dielectric constant higher than that of the first insulating film; and

a third insulating film formed at least within the trench.

According to a second aspect of the present invention, there is provided a method of manufacturing an electrically erasable nonvolatile semiconductor memory device, comprising:

forming a first insulating film on a semiconductor substrate;

forming a first conductive film on the first insulating film;

forming a second insulating film on the first conductive film, the second insulating film including a dielectric film having a dielectric constant higher than that of the first insulating film;

forming a second conductive film on the second insulating film;

etching the second conductive film, the second insulating film, the first conductive film, the first insulating film, and the semiconductor substrate by using a first pattern as a mask, to form a trench; and

forming a third insulating film within the trench.

### BRIEF DESCRIPTION OF THE SEVERAL VIEWS OF THE DRAWING

FIG. 1 is a plan view showing the construction of a semiconductor memory device according to a first embodiment of the present invention;

FIG. 2 is an equivalent circuit diagram of the semiconductor memory device shown in FIG. 1;

FIG. 3 is a cross-sectional view showing the construction of the semiconductor memory device according to the first embodiment of the present invention;

FIGS. 4A and 4B are cross-sectional views showing the construction of the semiconductor memory device according to the first embodiment of the present invention;

FIGS. 5A and 5B are cross-sectional views showing a part of the manufacturing process of the semiconductor memory device according to the first embodiment of the present invention;

FIGS. 6A and 6B are cross-sectional views showing a part of the manufacturing process of the semiconductor memory device according to the first embodiment of the present invention;

FIGS. 7A and 7B are cross-sectional views showing a part of the manufacturing process of the semiconductor memory device according to the first embodiment of the present invention;

FIGS. 8A and BB are cross-sectional views showing a part of the manufacturing process of the semiconductor memory device according to the first embodiment of the present invention;

FIGS. 9A and 9B are cross-sectional views showing a part of the manufacturing process of the semiconductor memory device according to the first embodiment of the present invention;

FIGS. 10A and 10B are cross-sectional views showing a part of the manufacturing process of the semiconductor memory device according to the first embodiment of the present invention;

FIGS. 11A and 11B are cross-sectional views showing a part of the manufacturing process of the semiconductor memory device according to the first embodiment of the present invention;

FIGS. 12A and 12B are cross-sectional views showing a part of the manufacturing process of the semiconductor memory device according to the first embodiment of the present invention;

FIGS. 13A and 13B are cross-sectional views showing a part of the manufacturing process of the semiconductor memory device according to the first embodiment of the present invention;

FIGS. 14A and 14B are cross-sectional views showing a modification of the first embodiment of the present invention;

FIGS. 15A and 15B are cross-sectional views showing a comparative case and a modification of the first embodiment of the present invention;

FIG. 16 is a cross-sectional view showing a modification of the first embodiment of the present invention;

FIG. 17 is a cross-sectional view showing a modification of the first embodiment of the present invention;

FIG. 18 is a cross-sectional view showing a modification of the first embodiment of the present invention;

FIGS. 19A and 19B are cross-sectional views showing a modification of the first embodiment of the present invention;

FIG. 20 is directed to the first embodiment of the present invention and shows the degree of exposure of a polysilicon film;

FIG. 21 is a cross-sectional view showing a modification of the first embodiment of the present invention;

FIG. 22 is a cross-sectional view showing a modification of the first embodiment of the present invention;

FIG. 23 is a plan view showing the construction of a semiconductor memory device according to a second embodiment of the present invention;

FIGS. 24A and 24B are cross-sectional views showing the construction of the semiconductor memory device according to the second embodiment of the present invention;

FIG. 25 is a cross-sectional view showing a part of the manufacturing process of the semiconductor memory device according to a third embodiment of the present invention;

FIG. 26 is a cross-sectional view showing a part of the manufacturing process of the semiconductor memory device according to the third embodiment of the present invention;

FIG. 27 is a cross-sectional view showing the construction of a semiconductor memory device according to a fourth embodiment of the present invention;

FIG. 28 is a cross-sectional view directed to a fifth embodiment of the present invention and showing the construction of an inter-polysilicon insulating film;

FIG. 29 is a cross-sectional view directed to the fifth embodiment of the present invention and showing the construction of an inter-polysilicon insulating film;

FIG. 30 is a cross-sectional view directed to the fifth embodiment of the present invention and showing the construction of an inter-polysilicon insulating film;

FIGS. 31A and 31B are cross-sectional views showing a part of the manufacturing process of a semiconductor memory device according to a sixth embodiment of the present invention;

FIGS. 32A and 32B are cross-sectional views showing a part of the manufacturing process of the semiconductor memory device according to the sixth embodiment of the present invention;

FIGS. 33A and 33B are cross-sectional views showing a part of the manufacturing process of the semiconductor memory device according to the sixth embodiment of the present invention;

FIGS. 34A and 34B are cross-sectional views showing a part of the manufacturing process of the semiconductor memory device according to the sixth embodiment of the present invention;

FIGS. 35A and 35B are cross-sectional views showing a part of the manufacturing process of the semiconductor memory device according to the sixth embodiment of the present invention; and

FIGS. 36A and 36B are cross-sectional views showing a part of the manufacturing process of the semiconductor memory device according to the sixth embodiment of the present invention.

### DETAILED DESCRIPTION OF THE INVENTION

Some embodiments of the present invention will now be described with reference to the accompanying drawings.

### Embodiment 1

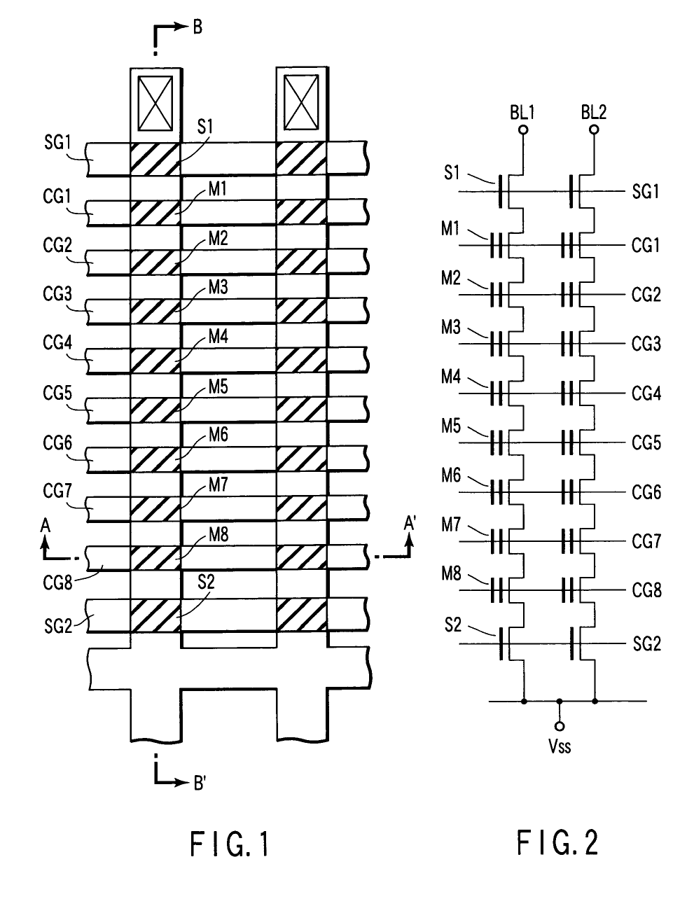

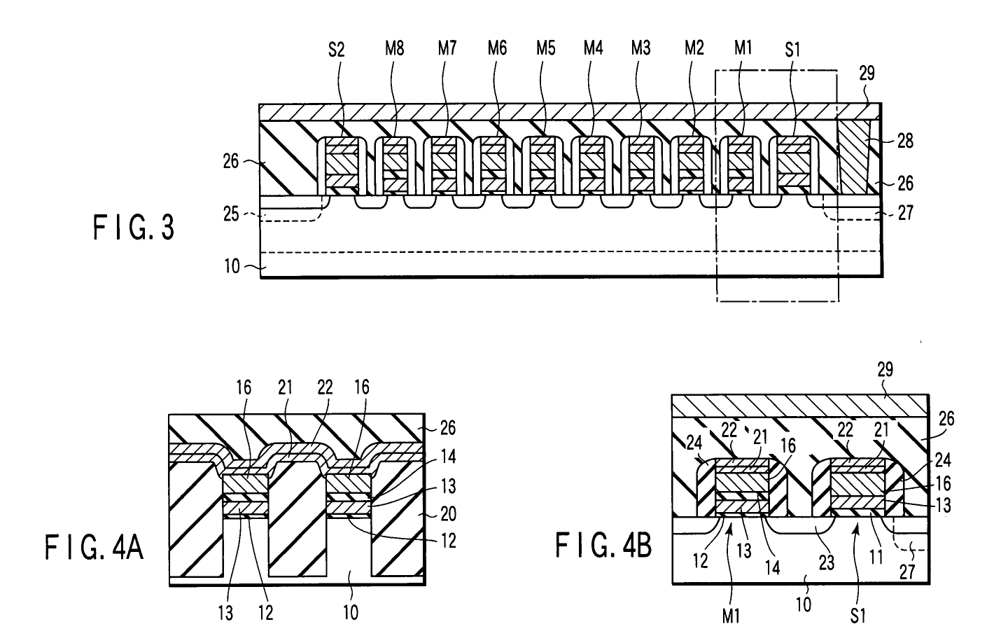

FIG. 1 is a plan view showing the construction of a NAND type flash memory (an electrically erasable nonvolatile semiconductor memory device) according to a first embodiment of the present invention. Incidentally, the bit lines are not shown in the drawing. FIG. 2 is an equivalent circuit diagram of the construction shown in FIG. 2. FIG. 3 is a cross-sectional view along the line B-B′ shown in FIG. 1. FIG. 4A is a cross-sectional view along the line A-A′ shown in FIG. 1. Further, FIG. 4B is a cross-sectional view showing the construction of a region corresponding to the region surrounded by a dash-and-dot line shown in FIG. 3.

As shown in FIGS. 1 and 2, each NAND cell unit is constructed such that memory cells M1 to M8 which are connected in series are arranged between select transistors S1 and S2. Select gate lines SG1 and SG2 are connected to the select transistor S1 and S2, respectively, and control gate lines (word lines) CG1 to CG8 are connected to the memory cells M1 to M8, respectively. Also, bit lines (BL1, BL2, etc.) are connected to the select transistors S1. Incidentally, eight memory cells are included in the NAND cell unit. However, the number of memory cells included in the NAND cell unit is not limited to eight. It is possible for sixteen memory cells or only one memory cell to be included. Where only one memory cell is included, it suffices to use a single select transistor.

As shown in FIGS. 3, 4A and 4B, the select transistors S1, S2 and the memory cells M1 to M8 are formed on a P-type silicon substrate (semiconductor substrate) 10.

Each of the memory cells M1 to M8 is provided with a gate structure including a tunnel insulating film (first insulating film) 12 formed on the silicon substrate 10, a floating gate (FG) electrode formed of a polysilicon film (first conductive film) 13, an inter-polysilicon insulating film (inter-polysilicon dielectrics; second insulating film) 14 formed of a metal oxide film, and a control gate (CG) electrode formed of a polysilicon film (second conductive film) 16. Also, each of the select transistors S1 and S2 is provided with a gate structure including a gate insulating film 11 formed on the silicon substrate 10 and a gate electrode formed of the polysilicon films 13 and 16.

An insulating film 20 for the isolation, which is formed within a trench for the isolation, is arranged between adjacent NAND cell units. A stacked film (third conductive film) of conductive films 21 and 22 is formed as a word line on the control gate electrode 16 and the insulating film 20. Also, a source/drain diffusion layer 23 is formed between the memory cells arranged within the NAND cell unit. Further, side wall spacer films are formed on the side walls of the select transistor and the memory cell.

The select transistor, the memory cell, etc. are covered with an interlayer insulating film 26, and a bit line 29 is formed on the interlayer insulating film 26. Also, source/drain diffusion layers 25 and 27 of a high impurity concentration are formed in a surface region of the silicon substrate 10, and the bit line 29 is connected to the high concentration source/drain diffusion layer 27 via a contact plug 28.

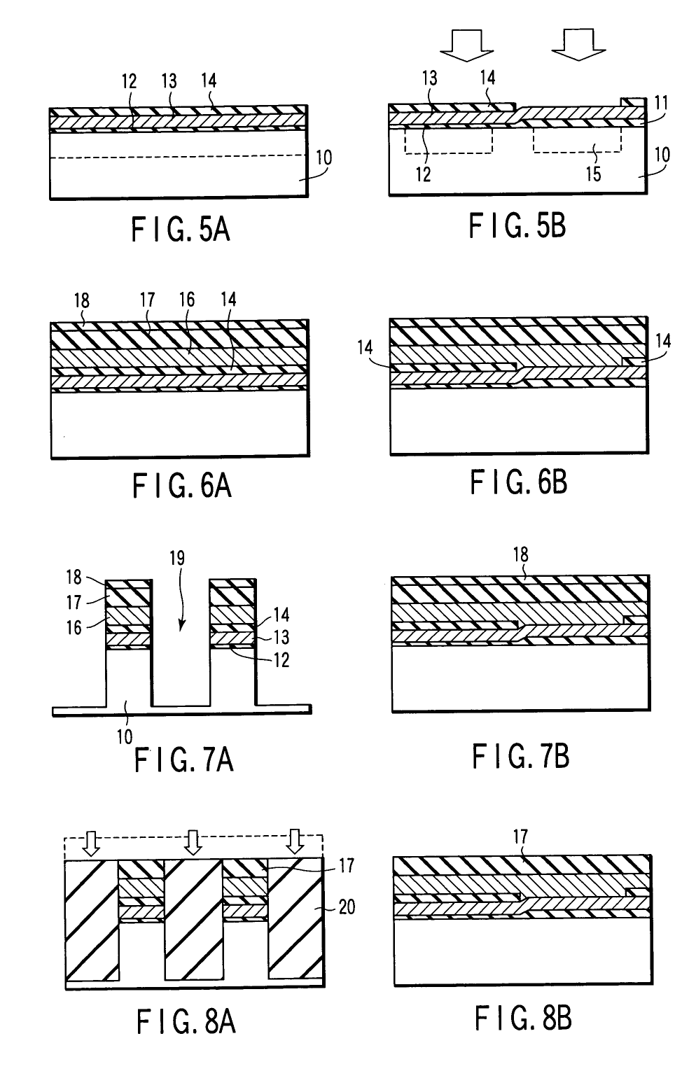

The manufacturing process of the semiconductor device according to the first embodiment of the present invention will now be described with reference to FIGS. 5A and 5B to FIGS. 13A and 13B. Incidentally, FIGS. 5A to 13A and FIGS. 5B to 13B correspond to FIGS. 4A and 4B, respectively.

In the first step, a P-well and an N-well are formed in a P-type silicon substrate 10 by employing lithography technology, ion implantation technology and annealing technology, as shown in FIGS. 5A and 5B. Then, a sacrificing oxide film (not shown) is formed on the surface of the silicon substrate 10, followed by forming a channel impurity layer 15 by employing lithography technology and ion implantation technology. After the sacrificing oxide film is removed, a gate insulating film 11 for a select transistor is formed. In this case, a silicon oxide film (SiO₂ film) having a thickness of about 15 nm is used as the gate insulating film 11.

In the next step, a gate insulating film 11 in a region in which a tunnel insulating film is to be formed is removed by etching. Then, a tunnel insulating film 12 is formed. A stacked film of a silicon oxide film and a silicon nitride film or a silicon oxynitride film obtained by nitriding a silicon oxide film can be used as the tunnel insulating film 12. For example, the tunnel insulating film 12 having a thickness of about 6 to 8 nm is formed by a thermal oxidation process or an oxynitridation process. Where a transistor of a high voltage system is required, the process described above is repeated so as to form a plurality of gate insulating films and tunnel insulating films differing from each other in film thickness.

Then, a polysilicon film 13 for a floating gate is formed in a thickness of, for example, about 100 nm. The conventional polysilicon film for the floating gate has a thickness of about 400 nm. Therefore, the thickness of the polysilicon film in the first embodiment is about ¼ of the thickness of the conventional polysilicon film. After formation of the polysilicon film 13, a high-K insulating film such as an alumina (Al₂O₃) film is formed on the polysilicon film 13 as an inter-polysilicon insulating film 14 in a thickness of about 14 nm by employing, for example, an ALD (Atomic Laser Deposition)-CVD method. Further, the alumina film 14 in a region in which a select transistor is to be formed is removed by etching so as to expose the surface of the polysilicon film 13 to the outside.

In the embodiment described above, the ion implantation for a channel was performed before formation of the tunnel insulating film. However, since the polysilicon film 13 is thin, it is possible to implant ions through the polysilicon film 13. Also, in the embodiment described above, the ALD-CVD method was employed for forming the alumina film 14. However, since the alumina film 14 is formed on a flat surface, it is possible to form the alumina film by employing a sputtering method. The leakage current through the alumina film can be suppressed by applying a heat treatment after formation of the alumina film.

In the next step, a polysilicon film 16 for a control gate is deposited in a thickness of about 200 nm, as shown in FIGS. 6A and 6B, followed by depositing a silicon nitride film 17 and a silicon oxide film 18, which are used for an etching mask, on the polysilicon film 16. Incidentally, since a stepped portion derived from the gate insulating film 11 or the alumina film 14 is formed below the silicon nitride film 17, a planarizing treatment by employing, for example, a CMP method may be carried out.

In the next step, a photoresist pattern (not shown) for forming a trench is formed on the silicon oxide film 18 by employing lithography technology, as shown in FIGS. 7A and 7B, followed by etching the silicon oxide film 18 and the silicon nitride film 17 by using the photoresist pattern as a mask. Further, the polysilicon film 16, the alumina film 14, the polysilicon film 13, the tunnel insulating film 12, the gate insulating film 11 and the silicon substrate 10 are successively etched by anisotropic dry etching technology such as RIE with the silicon oxide film 18 and the silicon nitride film 17 used as a mask. As a result, formed is a trench 19 for an STI (Shallow Trench Isolation). Since the etching is performed by using a single photoresist pattern, the side surfaces of the polysilicon film 16, the alumina film 14, the polysilicon film 13, the tunnel insulating film 12, the gate insulating film 11 and the silicon substrate 10 are aligned with each other. In this case, the trench 19 formed in the silicon substrate 10 has a depth of, for example, about 250 nm. Also, the trench 19 between the adjacent memory cells has a width of, for example, about 70 nm. Incidentally, since various trenches are formed in the substrate, trenches having various widths are also formed in the other regions.

In the example described above, the trench 19 having vertical side surfaces is formed in the silicon substrate. Alternatively, it is also possible to form a trench having inclined side surfaces as shown in FIGS. 14A and 14B. In the example shown in FIGS. 14A and 14B, the side surfaces of the trench are inclined by, for example, about 85°. It is also possible for the corner in the bottom portion of the trench to be shaped circular, i.e., to be curved, in a manner to have a radius of curvature of about 5 nm. The particular shape of the trench permits an insulating film to be buried in the trench easily. Also, it is possible to moderate the stress concentration in the corner in the bottom portion of the trench.

In the next step, the silicon substrate 10 is oxidized by means of ordinary thermal oxidation so as to form a thermal oxide film (not shown) in a thickness of about 4 nm on the side surface of the trench 19, as shown in FIGS. 8A and 8B. Incidentally, it is also possible to oxidize the side surface of the trench 19 by using oxygen radicals. In this case, it is possible to form a uniform and high quality silicon oxide film that is not dependent on the plane direction of silicon. Also, it is possible to employ an ISSG (In-Situ Steam Generation) method in this oxidizing step. In this case, the side surface of the silicon nitride film 17 is also oxidized slightly, which improves the bonding strength to an insulating film for the isolation, which is buried in the trench 19 in the subsequent step.

After the oxidizing step, the trench 19 is filled with an insulating film 20 for the isolation. In order to fill the trench 19 having a high aspect ratio with the insulating film 20, it is possible to use as the insulating film 20 an HDP-CVD-SiO₂ film or a coating film prepared by using a polysilazane as a source material. In the case of using these insulating films, it is possible to bury uniformly the insulating film in a trench having a large width and a trench having a small width simultaneously.

FIGS. 15A and 15B cover a case where an HDP-CVD-SiO₂ film having a thickness of 20 nm is used as the insulating film 20. In the conventional technology shown in FIG. 15A, it is necessary to increase the thickness of the polysilicon film 13 for the floating gate, with the result that it is difficult to bury satisfactorily the HDP-CVD-SiO₂ film in the trench. In the first embodiment of the present invention shown in FIG. 15B, however, it is possible to decrease the thickness of the polysilicon film 13. As a result, the total aspect ratio including the depth of the STI trench before filling with an insulating film is lowered, which makes it possible to bury satisfactorily the HDP-CVD-SiO₂ film in the trench.

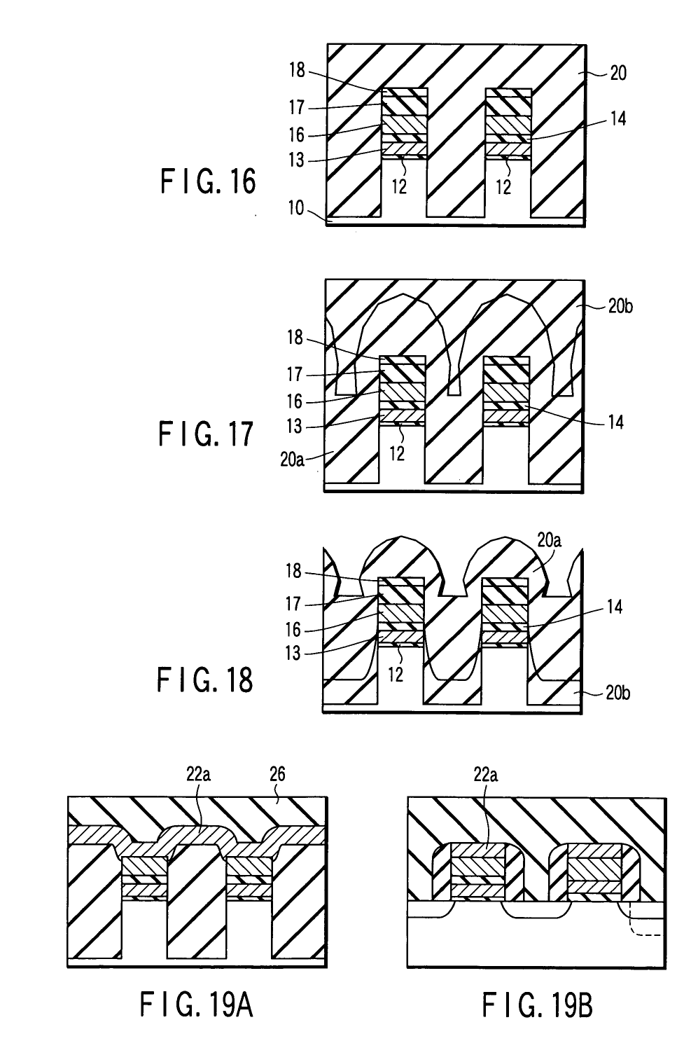

The case where the trench is filled with a coating film will now be described with reference to FIG. 16.

In the first step, the surface region is coated by a spin coating method with silazane peroxide polymer, i.e., polysilazane (PSZ), to a thickness of about 400 nm at the silicon flat portion. After the coating of the PSZ film, a baking treatment is applied at about 150° C. for about 3 minutes so as to evaporate the solvent contained in the coating material in the coating step. The burying characteristics achieved by the coating technology are satisfactory, and it is possible to bury the PSZ film in a narrow STI trench having a width of about 70 nm without leaving a void in the trench, as shown in FIG. 16.

Then, the PSZ film is converted into an SiO₂ film. This treatment is explained by the chemical formula given below:

SiH₂NH+20→SiO₂ +NH₃

As apparent from the chemical formula given above, the PSZ film reacts with oxygen (O) generated by the decomposition of steam (H₂O+O₂) so as to generate SiO₂ and NH₃ (ammonia). In this step, the element-forming region is covered with the silicon nitride film 17 and, thus, the surface of the silicon substrate in the element-forming region is not oxidized. To be more specific, a pyrogenic oxidation (BOX oxidation) is carried out for about 30 minutes under a steam atmosphere having a temperature of about 200° C. to 600° C. For example, if the BOX oxidation is carried out at 400° C. for about 30 minutes, the conversion from the Si—N bond into the Si—O bond is promoted. As a result, the PSZ film can be completely converted into an SiO₂ film in the trenches having various widths.

It is also possible to employ a two-stage BOX oxidation method in the BOX oxidation step. For example, an oxidation is performed for 30 to 60 minutes at about 200° C. in an atmosphere containing water vapor, followed by performing a heat treatment for about 30 minutes by elevating the temperature to about 400° C. to 50° C. in the water vapor atmosphere. In this case, it is possible to improve the conversion efficiency into an SiO₂ film. Also, it is possible to remove the impurities such as carbon remaining in the PSZ film. The two stage BOX oxidation method is particularly effective for conversion of a PSZ film into an SiO₂ film. Also, it is important to maintain the temperature at which the conversion into an SiO₂ is started, e.g., about 400° C., for a prescribed period of time. It is desirable to use a water vapor of a high concentration obtained by the hydrogen pyrogenic oxidation for providing the water vapor atmosphere. To be more specific, it is desirable for the water vapor atmosphere to contain at least 80% of the water vapor.

In the next step, a heat treatment is performed for about 30 minutes under temperatures falling within a range of between 700° C. and 1,000° C., e.g., at about 850° C., in an oxidative atmosphere or an inert gas atmosphere such as a nitrogen gas atmosphere. As a result, NH₃ and H₂O remaining in the SiO₂ film are released, which increases the density of the SiO₂ film. It follows that it is possible to obtain an SiO₂ film of a high density and to lower the leakage current. Where the heat treatment is carried out under an oxygen atmosphere, it is possible to further lower the concentration of the impurities such as carbon contained in the SiO₂ film. As a result, it is possible to lower the leakage current and to lower the fixed charge at the interface between the SiO₂ film and the silicon substrate. Also, where the heat treatment is carried out in an inert gas atmosphere such as a nitrogen gas atmosphere, it is possible to suppress the oxidation of the silicon substrate in the vicinity of the side surface of the STI trench and to suppress the reduction in the width of the element region, i.e., to suppress the increase in the width of the trench. In the densifying step, it is possible to employ an RTA (Rapid Thermal Annealing) or an RTO (Rapid Thermal Oxidation) in place of the ordinary heat treatment carried out by using a furnace. In the case of employing the RTA, the heat treatment can be performed under a higher temperature in a shorter time.

After formation of the insulating film 20 for the isolation as described above, the insulating film 20 is planarized by employing a CMP method. As a result, the surface of the silicon nitride film 17 is exposed to the outside. After the planarizing treatment by the CMP method, it is possible to apply a heat treatment at a temperature of about 850° C. In this case, it is possible to lower the wet etching rate of the PSZ film.

In the step of burying the insulating film 20 in the trench 19, it is possible to use in combination the HDP-CVD-SiO₂ film and the coating film. In the example shown in FIG. 17, an HDP-CVD-SiO₂ film 20a is formed first, followed by forming a coating film 20b such as a PSZ film so as to planarize the surface of the insulating film. On the other hand, in the example shown in FIG. 18, a coating film 20b such as a PSZ film is buried first in a lower portion of the trench, followed by applying a heat treatment so as to convert the PSZ film into an SiO₂ film. Then, an HDP-CVD-SiO₂ film 20a is formed. In each of these methods, a planarizing treatment is applied by using, for example, a CMP method.

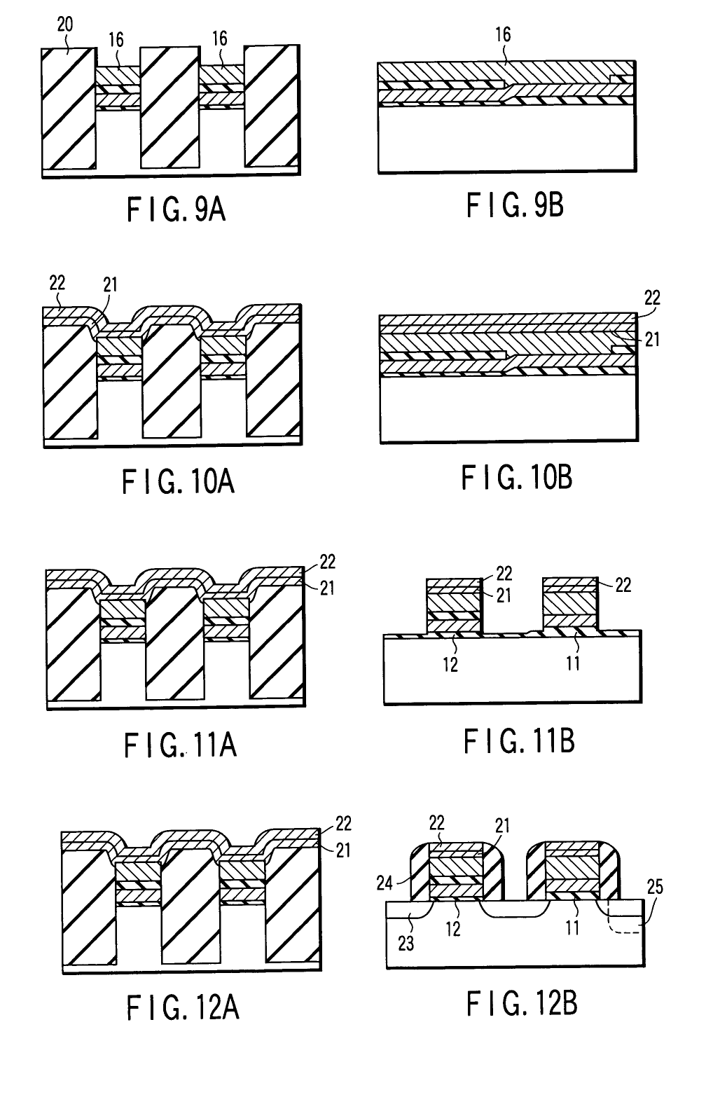

In the next step, the silicon nitride film 17 is selectively removed so as to expose the surface of the polysilicon film 16, as shown in FIGS. 9A and 9B. It is possible to use, for example, a hot phosphoric acid for the selective etching of the silicon nitride film 17.

After the selective removal of the silicon nitride film 17, a stacked film 21 of a TiN film and a Ti film and a tungsten silicide (WSi₂) film 22 having a low resistivity are formed on the entire surface, to a total thickness of about 20 nm, as shown in FIGS. 10A and 10B. The Ti film included in the stacked film 21 serves to achieve a low resistance contact with the polysilicon film 16. Incidentally, it is possible to form a silicon nitride film acting as a making layer on the upper surface of the silicide film 22.

In the example described above, the tungsten silicide film 22 is formed on the stacked film 21 formed of a TiN film and a Ti film. Alternatively, it is also possible to form a metal film having a low resistivity such as a tungsten film (W film) in place of the tungsten silicide film 22. Also, it is possible to use a single layer film such as a cobalt silicide (CoSi₂) film 22a, as shown in FIGS. 19A and 19B. Further, it is possible to use a polysilicon film in place of the stacked film 21 formed of a TiN film and a Ti film. Still further, it is possible to use nickel silicide or titanium silicide for forming the silicide film.

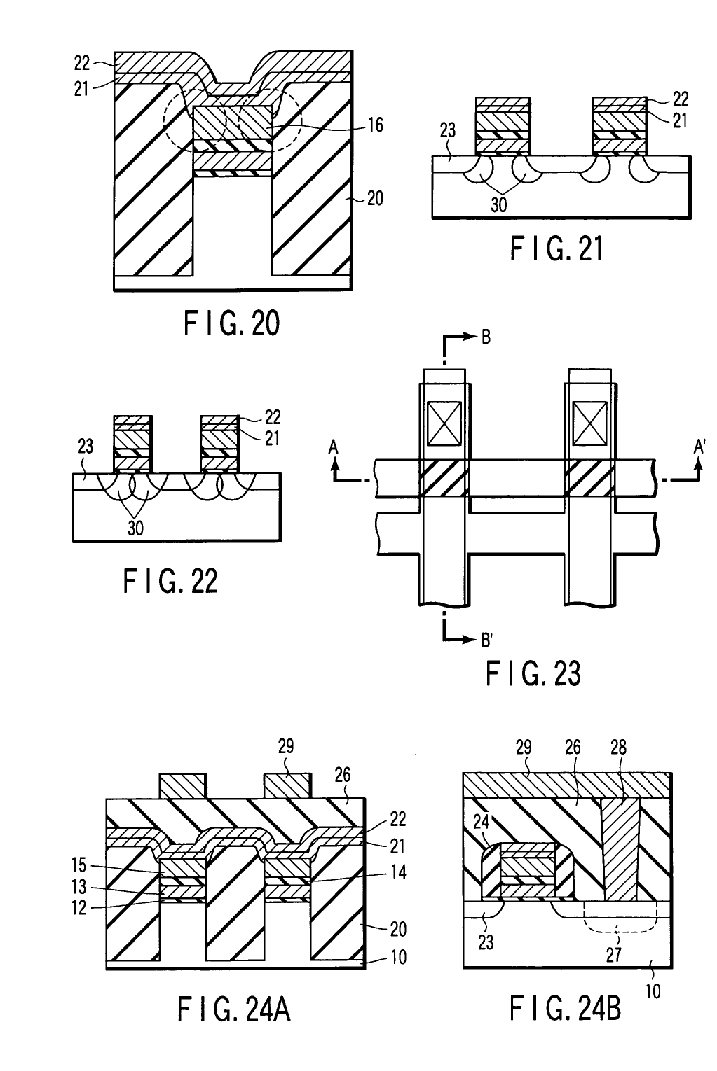

In general, a wet etching treatment using a diluted hydrofluoric acid is carried out as a pretreatment of the step for forming the stacked film 21 of a TiN film and a Ti film. In this case, it is possible for the silicon oxide film 20 to be also etched, exposing the side surface of the polysilicon film 16 to the outside as shown in FIG. 20. The degree of exposure of the side surface of the polysilicon film 16 differs depending on the etching rate of the silicon oxide film 20. In the first embodiment of the present invention, the side surface of the polysilicon film 16 is not utilized for forming a capacitor. Therefore, the capacitance ratio C2/C1 is not affected, even if the degree of exposure to the outside of the side surface of the polysilicon film 16 is changed. It suffices to control the etching depth such that the etching does not proceed to reach the floating gate.

In the next step, a photoresist pattern (not shown) is formed on the silicide film 22 by employing lithography technology, as shown in FIGS. 11A and 11B. Then, the silicide film 22, the TiN film/Ti film stacked film 21, the polysilicon film 16, the inter-polysilicon insulating film 14, and the polysilicon film 13 are successively etched by an anisotropic dry etching technology such as an RIE with the photoresist pattern used as a mask. As a result, formed is a gate structure for each of the memory cell and the select transistor together with a gate structure for a peripheral transistor (not shown). Incidentally, it is desirable to carry out the etching treatment under the conditions of a high etching selectivity ratio of SiO₂ to Si in order to prevent the surface of the silicon substrate 10 from being damaged in the etching step of the polysilicon film 13.

In the next step, the side surfaces of the polysilicon film 13 and the polysilicon film 16 are oxidized, followed by forming a source/drain diffusion layer 23 of a low impurity concentration by the ordinary lithography method and the ion implantation method, as shown in FIGS. 12A and 12B. Then, a side wall spacer film 24 is formed on the side surface of the gate structure. Further, a source/drain diffusion layer 25 of a high impurity concentration is formed by the ordinary lithography method and the ion implantation method. A similar process step is also applied to the P-channel transistor and the N-channel transistor included in the peripheral circuit so as to form an N⁺ diffusion layer and a P⁺ diffusion layer.

Incidentally, in order to prevent the punch-through of the transistor, it is possible to apply a halo ion implantation. For example, an ion implantation is performed by using the gate electrode as a mask so as to form an impurity layer 30 for preventing the punch-through, as shown in FIG. 21. Also, if the length of the gate electrode is decreased, the adjacent impurity layers 30 are caused to overlap with each other, as shown in FIG. 22. In such a case, it is possible to realize good transistor characteristics by optimizing the ion implantation amount.

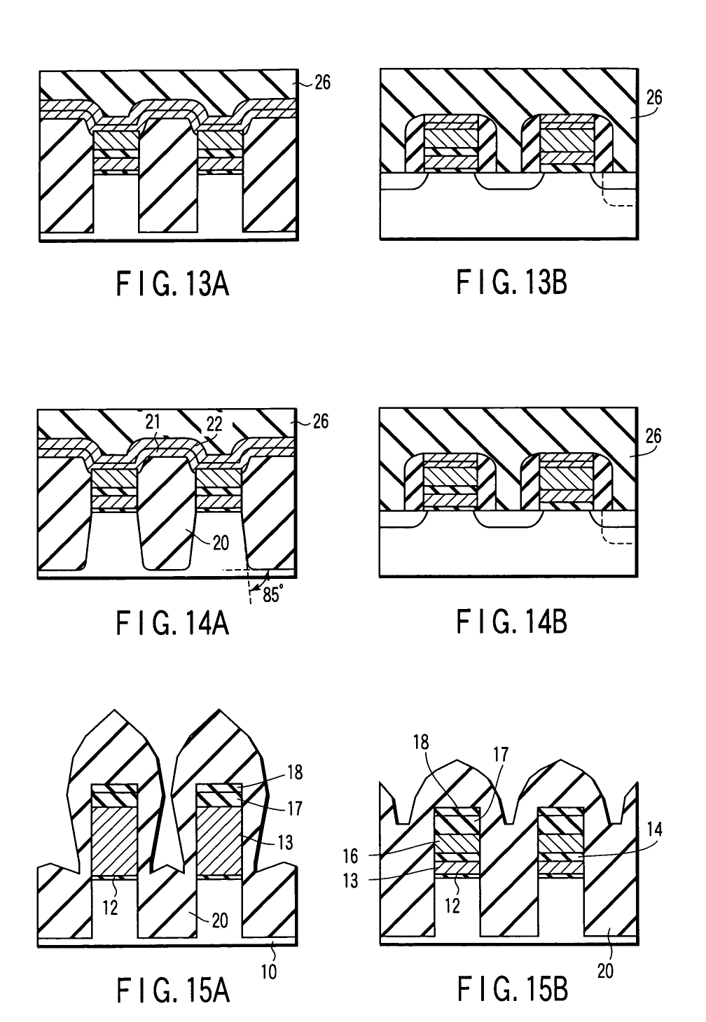

In the next step, an interlayer insulating film 26 is formed on the entire surface by a CVD method, as shown in FIGS. 13A and 13B, followed by planarizing the interlayer insulating film 26 by a CMP method.

Then, contact holes are formed, followed by forming contact plugs and subsequently forming bit lines so as to obtain the structure shown in FIGS. 4A and 4B. Further, an interlayer insulating film is formed and, then, a wiring layer is formed, followed by forming a passivation film and subsequently forming a pad, thereby finishing the manufacture of a semiconductor device.

As described above, according to the first embodiment of the present invention, the trench 19 for the isolation is formed by etching the polysilicon film 16, the inter-polysilicon film 14, the polysilicon film 13, the tunnel insulating film 12 and the silicon substrate 10 by using the same etching mask. It follows that the side surfaces of the polysilicon film (control gate) 16, the inter-polysilicon film 14, the polysilicon film (floating gate) 13, the tunnel insulating film 12 and the silicon substrate 10 are aligned with each other. In other words, the gate structure is formed in a self-aligned fashion relative to the insulating film 20 for the isolation.

What should be noted is that, in the first embodiment of the present invention, the capacitor is not formed by utilizing the side surface of the floating gate as in the prior art. As a result, it is unnecessary in the first embodiment of the present invention to control the exposed area on the side surface of the floating gate as in the prior art, and the capacitance C2 between the floating gate and the control gate can be maintained constant. It follows that, in the first embodiment of the present invention, it is possible to set constant the capacitance ratio C2/C1 of the capacitance C2 to the capacitance C1, i.e., the capacitance between the semiconductor substrate and the floating gate. Incidentally, the capacitance ratio C2/C1 is maintained constant at about 3 in general. Such being the situation, the first embodiment of the present invention makes it possible to suppress the nonuniformity in the electron injection amount into the floating gate, i.e., to suppress the nonuniformity in the data writing time, so as to improve the reliability and the yield.

Also, in the first embodiment of the present invention, the control gate is not positioned to face the corner in an upper portion of the floating gate as in the prior art. As a result, an increase in the leakage current can be prevented, which improves the reliability and the yield.

Also, in the first embodiment of the present invention, a capacitor is not formed by utilizing the side surface of the floating gate, which makes it possible to decrease the thickness of the floating gate. As a result, it is possible to decrease the total depth of the trench before the insulating film is buried in the trench. It follows that, even if the width of the trench is decreased, it is possible to bury the insulating film 20 for the isolation within the trench without fail, which improves the reliability and the yield. Also, since it is possible to decrease the thickness of the floating gate, it is possible to decrease the capacitance between the adjacent floating gates. It follows that it is possible to suppress the influence given by the adjacent memory cell, which realizes a stable operation.

Also, in the first embodiment of the present invention, a metal oxide film is used as the inter-polysilicon insulating film. It should be noted that the metal oxide film has in general a high dielectric constant, i.e., a dielectric constant not lower than 2 times as high as the dielectric constant of a silicon oxide film used as the tunnel insulating film. As a result, the capacitance C2 can be increased easily even if the side surface of the floating gate is not utilized for forming the capacitor as in the prior art, which can increase easily the capacitance ratio C2/C1 to exceed 2. It follows that it is possible to obtain an electrically rewritable nonvolatile semiconductor memory device producing the prominent effects described above without lowering the capacitance ratio C2/C1.

Further, in the first embodiment of the present invention, the side surfaces of the polysilicon film 16, polysilicon film 13 and the gate insulating film 11 are aligned with the side surface of the trench 19 for the isolation in the select transistor, too. In other words, each of the gate structure for the select transistor and the gate structure for the memory cell is self-aligned with the trench 19. It follows that it is possible to efficiently arrange the select transistor and the memory cell, which can simplify the manufacturing process.

### Embodiment 2

The first embodiment of the present invention described above is directed to a NAND type flash memory. However, a method similar to the method for the first embodiment can be employed for the manufacture of a NOR type flash memory.

FIG. 23 is a plan view showing the construction of a NOR type flash memory according to a second embodiment of the present invention. FIG. 24A is a cross sectional view along the line A-A′ shown in FIG. 23, and FIG. 24B is a cross sectional view along the line B-B′ shown in FIG. 23. The second embodiment is similar to the first embodiment in the basic construction and, thus, the constituting elements corresponding to the constituting elements for the first embodiment are denoted by the same reference numerals so as to avoid an overlapping description. The second embodiment is also similar to the first embodiment in the basic manufacturing method and, thus, the second embodiment of the present invention also permits producing the effects similar to those produced by the first embodiment of the present invention.

### Embodiment 3

In the first embodiment of the present invention described above, the silicon nitride film 17 was removed by a wet etching method using a hot phosphoric acid in the step shown in FIGS. 9A and 9B. In the third embodiment of the present invention, however, the silicon nitride film 17 is removed by a dry etching method. The third embodiment is similar to the first embodiment in the other basic construction and the manufacturing method.

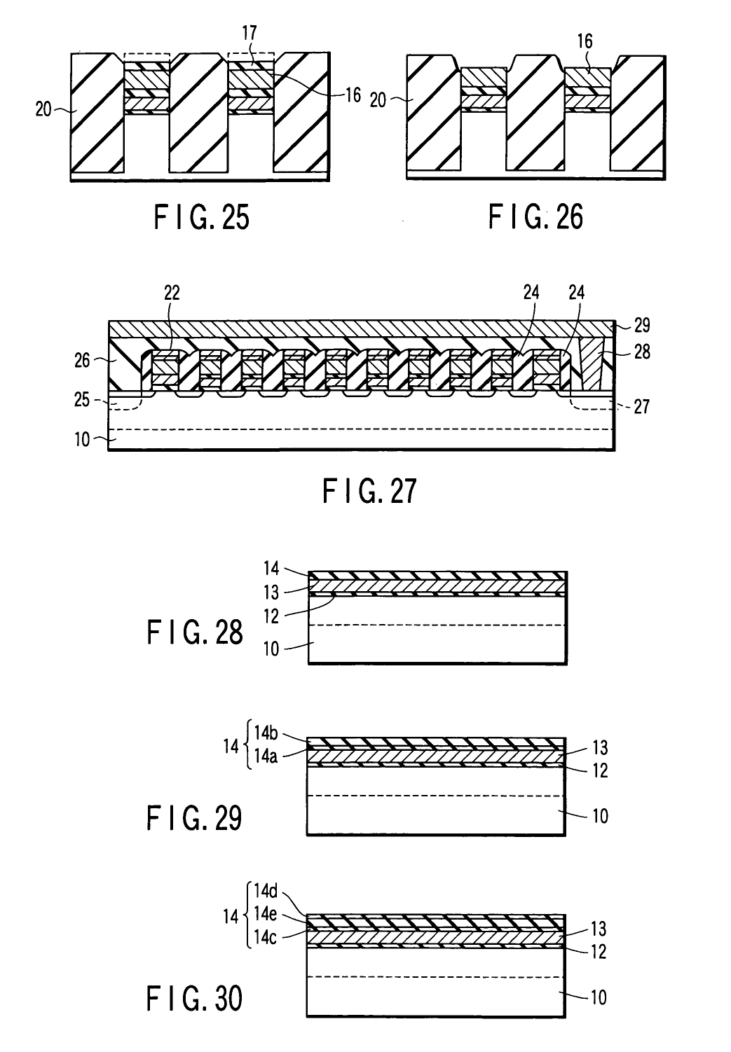

In the dry etching step referred to above, the etching is performed under the condition that the ratio of the etching rate of the silicon nitride film to the etching rate of the silicon oxide film is increased. The corner in the upper portion of the silicon oxide film 20 is made roundish because of the sputtering effect, as shown in FIG. 25. Further, in the stage that the dry etching proceeds to remove the silicon nitride film 17 completely, it is possible to make sufficiently obtuse the corner in the upper portion of the silicon oxide film 20, as shown in FIG. 26.

It follows that it is possible to solve the problem that the thickness of the silicide film 22 is rendered nonuniform in the vicinity of the corner in the upper portion of the silicon oxide film 20 when the silicide film 22, etc. is formed in the step shown in FIGS. 10A and 10B. As a result, it is possible to prevent, for example, the breakage of the silicide film 22 so as to obtain a nonvolatile memory having a high reliability.

### Embodiment 4

Where the distance between the adjacent memory cells is large, i.e., where the distance between the adjacent gate structures is large, the side wall spacer films 24 of the adjacent memory cells do not overlap with each other, as shown in FIGS. 3 and 4B. However, if the distance between the adjacent memory cells is small, the side wall spacer films 24 of the adjacent memory cells are caused to overlap with each other, as shown in FIG. 27. As a result, the capacitance between the adjacent gate structures generates a problem. In such a case, it is desirable to use a material having a low dielectric constant for forming the side wall spacer film 24. To be more specific, it is desirable to use a silicon oxide film having a dielectric constant lower than that of a silicon nitride film for forming the side wall spacer film 24.

In the fourth embodiment of the present invention, the capacitance between the adjacent gate structures is lowered by using a material having a low dielectric constant for forming the side wall spacer film. It follows that the fourth embodiment of the present invention makes it possible to suppress the influence given by the adjacent memory cell, which can realize a reliable operation. Also, it is possible to realize the structure in which the source/drain diffusion layers of a high impurity concentration are not formed in the cell region.

### Embodiment 5

A fifth embodiment of the present invention is directed to various modifications of the inter-polysilicon insulating film 14. To be more specific, an alumina film (Al₂O₃ film having a relative dielectric constant of about 12) is used as the inter-polysilicon insulating film 14 in the first embodiment of the present invention. However, various insulating films other than the alumina film can be used for forming the inter-polysilicon insulating film 14 as described below.

FIG. 28 exemplifies the case where the inter-polysilicon insulating film 14 is of a single layer structure. For example, it is possible to use a hafnium oxide film (HfO₂ film) as the inter-polysilicon insulating film. The HfO₂ film has a relative dielectric constant of about 20, which makes it possible to obtain a large capacitance C2 even if the capacitor area is small. Also, in addition to the Al₂O₃ film and the HfO₂ film, it is also possible to use various other metal oxide films such as a Ta₂O₅ film having a relative dielectric constant of about 25, a Ta₂O₅ film having Nb added thereto, i.e., Nb—Ta₂O₅ film, a Ta₂O₅ film having Ti added thereto, i.e., Ti—Ta₂O₅ film, an SrTiO₃ film having a relative dielectric constant of about 100 to 150, and a (Ba,Sr)TiO₃ film having a relative dielectric constant of about 250 to 350. These metal oxide films belong to a so-called “high-K insulating film”, which makes it possible to obtain a large capacitance C2 even if the area of the film is small. It is also possible to use a silicon nitride film (Si₃N₄ film having a relative dielectric constant of about 8) of a single layer structure as the inter-polysilicon insulating film 14.

FIGS. 29 and 30 exemplify the case where the inter-polysilicon insulating film 14 is of a stacked structure. To be more specific, it is possible to use a stacked film prepared by stacking two or more metal oxide films (14a and 14b in FIG. 29, 14c, 14d and 14e in FIG. 30) described above as the inter-polysilicon insulating film 14. For example, it is possible to use a stacked film of an Al₂O₃ film 14a having a thickness of about 3 nm and an HfO₂ film 14b having a thickness of about 10 nm.

FIG. 30 further exemplifies the case where a stacked film in which a metal oxide film 14e is interposed between nitride films 14c and 14d is used as the inter-polysilicon insulating film 14. In this case, each of the various metal oxide films exemplified above can be used as the metal oxide film 14e. It is desirable for each of the silicon nitride films 14c and 14d to have a thickness of, for example, about 2 nm. Concerning the thickness of the metal oxide film 14e, it is desirable for each of the Al₂O₃ film, the HfO₂ film, the Ta₂O₅ film, the Nb—Ta₂O₅ film, Ti—Ta₂O₅ film, and the (Ba,Sr)TiO₃ film to have a thickness of, for example, about 20 nm, and for the SrTiO₃ film to have a thickness of, for example, about 30 nm. In the case of using the silicon nitride films 14c and 14d in this fashion, it is possible to improve the reliability of the inter-polysilicon insulating film. Incidentally, it is possible to employ a stacked film structure including only one of the silicon nitride films 14c and 14d in order to increase the capacitance. Also, it is possible to use a silicon oxide film or a silicon oxynitride film in place of the silicon nitride films 14c and 14d. It is desirable to employ an ALD (Atomic Layer Deposition)-CVD method for forming these films.

### Embodiment 6

A NAND type flash memory according to a sixth embodiment of the present invention will now be described.

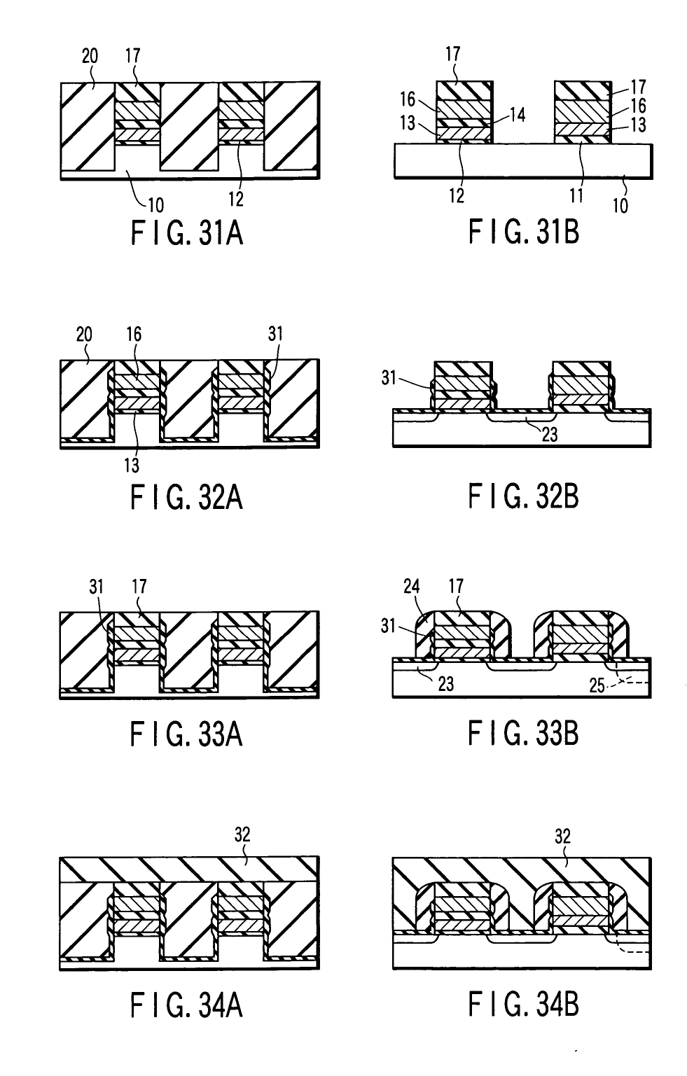

FIGS. 31A to 36A and 31B to 36B are cross sectional views showing a manufacturing method of a NAND type flash memory according to a sixth embodiment of the present invention. Incidentally, the sixth embodiment is equal to the first embodiment up to the step shown in FIGS. 8A and 8B in conjunction with the first embodiment of the present invention. Therefore, the subsequent steps will now be described.

After the step shown in FIGS. 8A and 8B, a photoresist pattern (not shown) is formed on the silicon nitride film 17 and the insulating film (silicon oxide film) 20 for the isolation by lithography technology, as shown in FIGS. 31A and 31B. Then, the silicon nitride film 17, the polysilicon film 16, the inter-polysilicon insulating film 14, and the polysilicon film 13 are successively etched by anisotropic etching technology such as RIE with the photoresist pattern used as a mask. As a result, the gate structures of the memory cell and the select transistor are formed together with the gate structure of a peripheral transistor (not shown). Incidentally, it is desirable to carry out the etching treatment under the conditions of a high etching selectivity ratio of SiO₂ to Si in order to prevent the surface of the silicon substrate 10 from being damaged in the etching step of the polysilicon film 13.

In the next step, the side surfaces of the polysilicon film (control gate electrode) 16 and the polysilicon film (floating gate electrode) 14 are oxidized so as to form a silicon oxide film 31, followed by forming a source/drain diffusion layer 23 by employing ordinary lithography technology and ion implantation technology, as shown in FIGS. 32A and 32B.

In the next step, a side wall spacer film 24 is formed on the side surface of the gate structure, as shown in FIGS. 33A and 33B, followed by forming a source/drain diffusion layer 25 of a high impurity concentration by the ordinary lithography method and the ion implantation method. A similar treatment is applied to a P-channel transistor region and an N-channel transistor region included in the peripheral circuit so as to form an N⁺ diffusion layer and a P⁺ diffusion layer.

Further, an interlayer insulating film 32 is formed on the entire surface by a CVD method, followed by planarizing the interlayer insulating film 32 by a CMP method, as shown in FIGS. 34A and 34B.

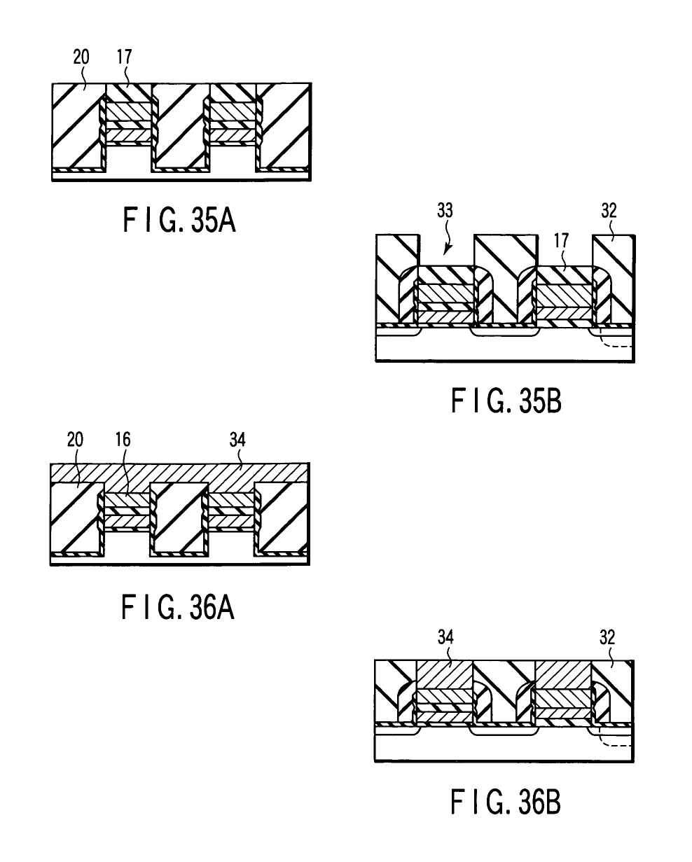

In the next step, the interlayer insulating film 32 is processed by the ordinary lithography method and the RIE method so as to expose the upper surface of the silicon nitride film 17 to the outside, as shown in FIGS. 35A and 35B. As a result, a trench 33 for a word line is formed. Incidentally, it suffices to ensure an electrical connection between the control gate electrode 16 and the word line formed within the trench 33 even if the pattern of the trench 33 may be slightly deviated from the pattern of the control gate electrode 16.

In the next step, the silicon nitride film 17 is selectively removed, followed by depositing by a CVD method a tungsten silicide film (WSi₂ film) 34 on the entire surface in a thickness of about 200 nm, as shown in FIGS. 36A and 36B. Incidentally, it is possible to form a metal film having a lower resistivity such as a tungsten film in place of the WSi₂ film. Then, the tungsten silicide film 34 is buried in the trench 33 by employing a CMP method so as to form a word line 34.

Then, contact holes are formed, followed by forming contact plugs and subsequently forming bit lines. Further, an interlayer insulating film is formed and, then, a wiring layer is formed, followed by forming a passivation film and subsequently forming a pad, thereby finishing the manufacture of a semiconductor device.

Effects similar to those obtained in the first embodiment of the present invention are also obtained in the sixth embodiment of the present invention. Further, an additional effect can be obtained in the sixth embodiment of the present invention. Specifically, in the first embodiment of the present invention, the silicide film 22 for the word line is already formed in forming the gate structure in the step shown in FIGS. 11A and 11B, with the result that the silicide film is also oxidized in oxidizing the side surface of the gate structure. Such being the situation, the oxidizing conditions are much restricted. In the sixth embodiment, however, the silicide film 34 providing a word line is formed in the step shown in FIGS. 36A and 36B after formation of the gate structure in the step shown in FIGS. 31A and 31B. It follows that the conditions for oxidizing the side surface of the gate structure are not particularly limited, and a desired oxide film can be formed on the side surface of the gate structure, which improve the reliability of the nonvolatile memory.

Needless to say, various modifications described previously in conjunction with the first to fifth embodiments described above can also be achieved in the sixth embodiment of the present invention.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electrically erasable nonvolatile semiconductor memory device, comprising:
a semiconductor substrate having a trench and a projecting portion which has a first side surface defined by the trench;
a first gate structure comprising a first insulating film formed on the projecting portion and having a first side surface aligned with the first side surface of the projecting portion, a first conductive film formed on the first insulating film and having a first side surface aligned with the first side surface of the first insulating film, a second insulating film formed on the first conductive film and having a first side surface aligned with the first side surface of the first conductive film, and a second conductive film formed on the second insulating film and having a first side surface aligned with the first side surface of the second insulating film, the second insulating film including a dielectric film having a dielectric constant higher than that of the first insulating film; and
a third insulating film formed at least within the trench.

2. The semiconductor memory device according to claim 1, wherein the first side surfaces of the projecting portion, the first insulating film, the first conductive film, the second insulating film and the second conductive film are positioned substantially within the same plane.

3. The semiconductor memory device according to claim 1, wherein an upper surface of the third insulating film is positioned higher than an upper surface of the first conductive film.

4. The semiconductor memory device according to claim 1, wherein:
the first conductive film has a second side surface perpendicular to the first side surface of the first conductive film;
the second insulating film has a second side surface perpendicular to the first side surface of the second insulating film and aligned with the second side surface of the first conductive film; and
the second conductive film has a second side surface perpendicular to the first side surface of the second conductive film and aligned with the second side surface of the second insulating film.

5. The semiconductor memory device according to claim 4, further comprising a third conductive film formed on the first gate structure and the third insulating film.

6. The semiconductor memory device according to claim 5, wherein a side surface of the third conductive film is aligned with the second side surface of the second conductive film.

7. The semiconductor memory device according to claim 1, wherein the dielectric film is formed of a metal oxide film.

8. The semiconductor memory device according to claim 1, wherein a capacitance between the first conductive film and the second conductive film is larger than a capacitance between the semiconductor substrate and the first conductive film.

9. The semiconductor memory device according to claim 1, wherein a capacitance between the first conductive film and the second conductive film is as large as at least twice a capacitance between the semiconductor substrate and the first conductive film.

10. The semiconductor memory device according to claim 1, wherein a dielectric constant of the dielectric film is as large as at least twice a dielectric constant of the first insulating film.

11. The semiconductor memory device according to claim 1, wherein the second insulating film further includes at least one of a silicon nitride film formed between the dielectric film and the first conductive film and a silicon nitride film formed between the dielectric film and the second conductive film.

12. The semiconductor memory device according to claim 1, further comprising a second gate structure comprising a fourth insulating film formed on the projecting portion and having a first side surface aligned with the first side surface of the projecting portion, a first film formed on the fourth insulating film, having a first side surface aligned with the first side surface of the fourth insulating film and equivalent to the first conductive film, and a second film formed on the first film, having a first side surface aligned with the first side surface of the first film and equivalent to the second conductive film.

13. A method of manufacturing an electrically erasable nonvolatile semiconductor memory device, comprising:
forming a first insulating film on a semiconductor substrate;
forming a first conductive film on the first insulating film;
forming a second insulating film on the first conductive film, the second insulating film including a dielectric film having a dielectric constant higher than that of the first insulating film;
forming a second conductive film on the second insulating film;
etching the second conductive film, the second insulating film, the first conductive film, the first insulating film, and the semiconductor substrate by using a first pattern as a mask, to form a trench; and
forming a third insulating film within the trench.

14. The method according to claim 13, further comprising:
forming a third conductive film on the second conductive film and the third insulating film; and
etching the third conductive film, the second conductive film, the second insulating film, and the first conductive film by using as a mask a second pattern perpendicular to the first pattern.

15. The method according to claim 13, further comprising:
etching, after forming the third insulating film, the second conductive film, the second insulating film and the first conductive film by using as a mask a second pattern perpendicular to the first pattern; and
forming a pattern of a third conductive film parallel to the second pattern, on the second conductive film and the third insulating film.
